(19) United States
(12) Patent Application Publication
(10) Pub. No.: US 2022/0052408 A1
(43) Pub. Date: Feb. 17, 2022

(54) SHEAR WALL WITH INTEGRATED CONDUCTORS

(71) Applicant: Rivian IP Holdings, LLC, Plymouth, MI (US)

(72) Inventors: Nathaniel Christopher Wynn, Newport Beach, CA (US); Kyle William Butterfield, Rancho Santa Margarita, CA (US); Tyler David Collins, Irvine, CA (US)

(21) Appl. No.: 17/386,353

(22) Filed: Jul. 27, 2021

Related U.S. Application Data
(63) Continuation of application No. 15/937,794, filed on Mar. 27, 2018, now abandoned.

(51) Int. Cl. H01M 50/209; H01M 10/42; H01M 10/48; H05K 1/02; H01M 50/20; H01M 50/502; H01M 50/528

(52) U.S. Cl. CPC H01M 50/209; H01M 10/425; H01M 10/482; H05K 1/0265; H01M 10/486; H05K 1/0366; H01M 50/502; H01M 50/528; H05K 2201/10196; H05K 2201/012; H01M 50/20

(57) ABSTRACT

A battery system includes one or more shear walls to provide support. A shear wall may include a support structure and conductive traces to route signals or measurements without the need for wire runs. The support structure may help to maintain the arrangement of battery cells of the battery system, while the conductive traces allow voltages among the battery cells to be monitored. Busbars, or other electrical terminals, may be coupled to the conductive traces of the shear wall, and processing equipment may also be coupled to the conductive traces. Accordingly, the processing equipment may monitor voltage among the battery cells, which may allow balancing among battery modules, diagnostics, and other functions. The shear wall may be constructed of FR-4 or other circuit board material, and the conductive traces may include bonded copper, or other electronically conductive material.

This application is a continuation of U.S. patent application Ser. No. 15/937,794, filed Mar. 27, 2018, which is hereby incorporated by reference herein in its entirety.

### BACKGROUND

Battery packs for electrical vehicles are sometimes housed to protect them from vehicle crashes, vibration, and stresses that may impact the structure. Typical battery packs include groups of battery cells connected in parallel to increase current flow, and in series to increase voltage. Measurements and monitoring of the battery cells, or groups thereof, typically require wires to be routed within the battery pack. It is also usually non-trivial to make electrical connections between a wire and a busbar. It would be advantageous to reduce the use of wire and connectors for monitoring a battery pack. It would also be advantageous to not have to include wire runs within the battery pack.

### SUMMARY

In some embodiments, a shear wall is configured to provide structural support to a battery system. The shear wall includes a support structure that is configured to provide rigidity to the battery system along at least one side of the battery system. The shear wall also includes a plurality of conductive traces layered onto the support structure. The plurality of conductive traces each include a first terminal configured to be coupled to a busbar of the battery system and a second terminal configured to be coupled to processing equipment. Accordingly, the conductive traces allow the processing equipment to measure, and optionally monitor, the voltage at one or more busbars, without having to install wire runs. In some embodiments, a busbar is connected to respective like-polarity terminals of a group of battery cells.

In some embodiments, the shear wall also includes at least one temperature sensor affixed to the support structure and corresponding conductive traces. These conductive traces include a first terminal configured to be coupled to the at least one temperature sensor, and a second terminal configured to be coupled to the processing equipment. Accordingly, the conductive traces allow the processing equipment to receive signals from one or more sensors, without having to install wire runs. In an illustrative example, a temperature sensor includes a thermistor, a thermocouple, or a resistance temperature detector.

In some embodiments, the shear wall includes an electrical connector, which includes respective pins coupled to each of the respective second terminals. In some embodiments, the processing equipment is coupled to a second electrical connector, and each of the second terminals is configured to be coupled to the processing equipment by connecting the first electrical connector and the second electrical connector. For example, a cable having plugs at both ends may couple the first and second connectors so that the processing equipment may measure voltages of the second terminals.

In some embodiments, the support structure is made at least in part of a flame-resistant glass-epoxy laminate. In some embodiments, the conductive traces include copper tracks bonded to the support structure. In some embodiments, the conductive traces may include gold, silver, or other metals. In some embodiments, the support structure includes at least one extension (e.g., a tab or other protrusion), which includes a conductive pad. The conductive pad is coupled to a first terminal, and the conductive pad is configured to be coupled to the busbar. Accordingly, the extension provides a coupling location for electrically coupling a busbar to conductive traces of the shear wall. For example, in some embodiments, a first terminal is configured to be coupled to the busbar by a screw terminal. In a further example, in some embodiments, the first terminal is configured to be coupled to the busbar by a welded connection.

In some embodiments, the shear wall is included in a battery system. For example, a battery system includes processing equipment, a plurality of battery cells connected to a plurality of busbars, at least one shroud, and a shear wall. The at least one shroud is configured to maintain an arrangement of the plurality of battery cells. The shear wall is configured to provide structural support to the at least one shroud and the arrangement of the plurality of battery cells. The shear wall includes a support structure coupled to the at least one shroud along at least one side of the at least one shroud. The shear wall also includes a plurality of conductive paths affixed to the support structure. The plurality of conductive paths each include a respective first terminal configured to be coupled to a respective busbar, and a respective second terminal configured to be coupled to the processing equipment.

### BRIEF DESCRIPTION OF THE DRAWINGS

The present disclosure, in accordance with one or more various embodiments, is described in detail with reference to the following figures. The drawings are provided for purposes of illustration only and merely depict typical or example embodiments. These drawings are provided to facilitate an understanding of the concepts disclosed herein and shall not be considered limiting of the breadth, scope, or applicability of these concepts. It should be noted that for clarity and ease of illustration these drawings are not necessarily made to scale.

FIG. 1 shows a plan view of an illustrative shear wall having integrated conductors, and processing equipment, in accordance with some embodiments of the present disclosure;

FIG. 2 shows a plan view of an illustrative shear wall having integrated conductors, and connectors, in accordance with some embodiments of the present disclosure;

FIG. 3 shows a cross-section view of an illustrative battery system, in accordance with some embodiments of the present disclosure;

FIG. 4 shows a side view of an illustrative battery system, in accordance with some embodiments of the present disclosure;

FIG. 5 shows a top view of the illustrative battery system of FIG. 4, in accordance with some embodiments of the present disclosure;

FIG. 6 shows a perspective view of an exploded battery system structure, including shrouds and shear walls, in accordance with some embodiments of the present disclosure; and

FIG. 7 shows a cross-section view of a portion of an illustrative battery system, including two battery modules, and processing equipment, in accordance with some embodiments of the present disclosure.

### DETAILED DESCRIPTION

A battery system may include an arranged (e.g., hexagonally close-packed) group of battery cells with parallel axes, with corresponding buttons (e.g., ends having like polarity) pointed in the same direction, a plastic shroud at either end of the collective cells (e.g., to provide support and maintain the arrangement), a set of busbars mounted to the shroud at the button ends of the cells (e.g., to couple cells to one another in series and parallel), and a shear wall arranged along at least one side of the battery system configured to provide structural rigidity.

In some embodiments, the shear wall is substantially a piece of nonconductive, fiber-reinforced composite. For example, the shear wall may be constructed of a flame-retardant fiberglass. In a further example, the shear wall may be constructed of a composite that fulfills the requirements of NEMA LI 1-1998 Grade FR-4. In a further example, the shear wall may be constructed from an injection-molded or pressure-formed, fiber-reinforced polymer.

In some embodiments, a shear wall may include a printed circuit, embedded circuit, or other suitable collection of conductors, which may be coupled to the busbars, battery cells, or both. In some embodiments, the shear wall may include conductive traces that electrically connect to respective pads on the shear wall, which may be electrically connected to a respective busbar.

In some embodiments, a battery system may include processing equipment that at least partially monitors or controls the voltage balance among one or more battery systems. Accordingly, the processing equipment may be configured to measure one or more voltage signals from one or more busbars, one or more cells, or both. The integration of conductive traces in the shear wall may provide easy-to-use and fast-to-install electrical connections between processing equipment and busbars without significant added cost (e.g., from running and terminating wires, and accompanying cable management).

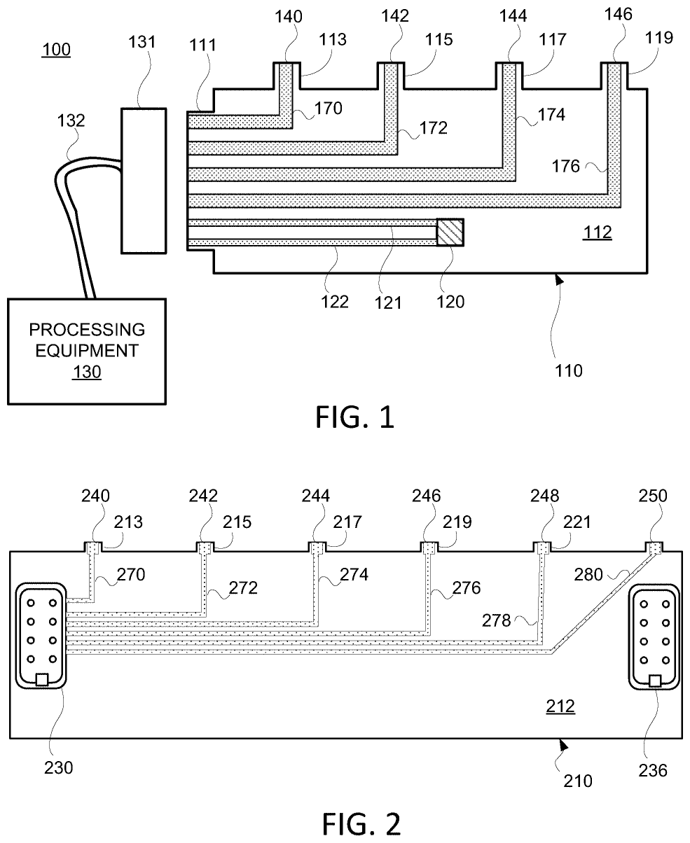

FIG. 1 shows arrangement 100, including a plan view of illustrative shear wall 110 having integrated conductors (e.g., conductive traces 170, 172, 174, and 176), and processing equipment 130, in accordance with some embodiments of the present disclosure. Shear wall 110 may represent one side wall of a battery module, providing structural support and rigidity as well as conductive traces for routing electrical measurements. Shear wall 110 includes a support structure 112, which may be configured to, for example, provide rigidity to components of a battery module. Shear wall 110 includes extensions 113, 115, 117, and 119, having corresponding first terminals 140, 142, 144, and 146. First terminals 140, 142, 144, and 146 may be configured to be coupled to corresponding busbars, battery cells, or both.

Processing equipment 130 may include any suitable circuitry for processing signals received from conductive traces of shear wall 110 (e.g., via cable 132 and connector 131). For example, processing equipment 130 may include signal conditioning circuitry (e.g., filters, amplifiers, voltage dividers), an analog to digital converter, any other suitable circuitry, or any combination thereof. Processing equipment 130 may, in some embodiments, include a processor, a power supply, power management components (e.g., relays, filters, voltage regulators), input/output IO (e.g., GPIO, analog, digital), memory, communications equipment (e.g., CANbus hardware, Modbus hardware, or a WiFi module), any other suitable components, or any combination thereof. In some embodiments, processing equipment 130 may include one or more microprocessors, microcontrollers, digital signal processors, programmable logic devices, field-programmable gate arrays (FPGAs), application-specific integrated circuits (ASICs), etc., and may include a multi-core processor. In some embodiments, processing equipment 130 may be distributed across multiple separate processors or processing units, for example, multiple of the same type of processing units or multiple different processors.

In some embodiments, processing equipment 130 executes instructions stored in memory for monitoring a battery system, managing a battery system, or both. In some embodiments, memory may be an electronic storage device that is part of processing equipment 130. For example, memory may be configured to store electronic data, computer software, or firmware, and may include random-access memory, read-only memory, hard drives, optical drives, solid state devices, or any other suitable fixed or removable storage devices, and/or any combination of the same. Nonvolatile memory may also be used (e.g., to launch a boot-up routine and other instructions).

In some embodiments, processing equipment 130 may be coupled to more than one shear wall (e.g., via any suitable number of cables and connectors), corresponding to more than one battery module or more than one section of a battery module. For example, processing equipment 130 may be configured to balance load across the battery modules based on measured voltages.

Shear wall 110 includes sensor 120, and corresponding conductive traces 121 and 122 for communicating sensor data from sensor 120, powering sensor 120, or both. Sensor 120 may include any suitable sensor such as, for example, a voltage sensor, a current sensor, an impedance sensor, a strain sensor (e.g., a strain gage connected to a Wheatstone Bridge circuit), a vibration sensor (e.g., a piezoelectric accelerometer), an optical sensor (e.g., a camera, photodetector, or photodiode), a proximity sensor (e.g., an ultrasound source and detector, or an infrared based system), any other suitable sensor, any suitable corresponding circuitry, or any combination thereof. In some embodiments, for example, a sensor may include surface-mount packaging (e.g., a surface-mount integrated circuit), through-hole packaging, or a combination thereof. In accordance with the present disclosure, a sensor may be bolted to, adhered to, welded to, printed on, embedded within, or otherwise affixed to, a support structure.

Sensor 120 may include, for example, any suitable type of temperature sensor such as a thermocouple, a thermopile, a thermistor, a resistive temperature detector (RTD), any other suitable temperature sensor, or any combination thereof. For example, in some embodiments, sensor 120 may include a thermistor connected across conductive traces 121 and 122. In some such embodiments, processing equipment 130 may be configured to measure a voltage across conductive traces 121 and 122 to determine a corresponding temperature of sensor 120, which may be indicative of a local temperature of shear wall 110. In a further example, in some embodiments, sensor 120 may include a thermocouple junction connected across conductive traces 121 and 122, which may include suitable respective metals corresponding to the thermocouple junction. In some such embodiments, processing equipment 130 may include a cold junction (e.g., which may be measured using a thermistor), and may be configured to measure a voltage across conductive traces 121 and 122, to determine a corresponding temperature of sensor 120 (e.g., based on the voltage, and the temperature of the cold junction), which may be indicative of a local temperature of shear wall 110. In some embodiments, a sensor may require more than two conductive traces. For example, in some embodiments, a sensor may include an RTD, which may require four conductive traces for an accurate measurement (e.g., using a four-wire measurement). In some embodiments, a sensor may require a single conductive trace. For example, a sensor may include a thermistor which may be grounded at one terminal, and only a single conductive trace is used (e.g., the processing equipment may measure the voltage of the single trace relative to a common ground). A shear wall, in accordance with the present disclosure, need not include any sensors, but may include any suitable number of sensors, each having any suitable number of corresponding conductive traces.

In some embodiments, shear wall 110 also includes first extension 111, which may include second terminals corresponding to respective first terminals (e.g., connected by respective conductive traces). First extension 111 may be configured to engage with a connector (e.g., connector 131), to couple conductive traces to conductors of the connector. In some embodiments, a shear wall need not include a first extension. For example, a shear wall may include a plurality of second terminals which may be respectively coupled to pins of an included connector, which may be configured to engage with a mating connector to couple the conductive traces to processing equipment.

As shown in FIG. 1, support structure 112 is a rectangle, having several extensions (e.g., extensions 113, 115, 117, and 119, and first extension 111). In some embodiments, support structure 112 may be formed by being cut from a larger sheet of material. In some embodiments, for example, support structure 112 may be an injection-molded, or pressure-formed, fiber-reinforced polymer.

In some embodiments, conductive traces 170, 172, 174 and 176 may be formed on support structure 112 using printed circuit board (PCB) techniques. For example, a copper foil may be applied to support structure 112, and etched away (e.g., chemically etched) to leave conductive traces 170, 172, 174, and 176. In a further example, a copper foil may be applied to support structure 112, a photoresist applied, and excess copper may be etched away to leave conductive traces 170, 172, 174, and 176. In some embodiments, a multi-layer collection of conductive traces may be formed, wherein conductive traces may be separated by a layer of the support structure. In some embodiments, one or more ground planes (e.g., connected to a DC low output of a power supply, shielding, or chassis ground), power planes (e.g., connected to a DC high output of a power supply), or any other suitable conductive layers may be included in a shear wall. Conductive traces 170, 172, 174, and 176 may be formed using any suitable conductor such as, for example, copper, gold, silver, platinum, aluminum, graphite, an alloy, or a combination thereof, and need not all include the same material.

FIG. 2 shows a plan view of illustrative shear wall 210 having integrated conductors (e.g., conductive traces 270, 272, 274, 276, 278, and 280), and connectors 230 and 236, in accordance with some embodiments of the present disclosure. Shear wall 210 includes support structure 212, which may be configured to mechanically engage with components of a battery module to provide rigidity. Conductive traces 270, 272, 274, 276, 278, and 280 connect respective pads 240, 242, 244, 246, 248, and 250 to respective pins of connector 230. Another set of conductive traces, not shown in FIG. 2 (e.g., included on a different layer of support structure 212), connect pads 240, 242, 244, 246, 248, and 250 to respective pins of connector 236, such that processing equipment may be coupled to connector 230, connector 236, or both, via a corresponding connector, to measure, for example, respective voltages. Pads 240, 242, 244, 246, 248, and 250 are positioned on respective extensions 213, 215, 217, 219, and 221, and are configured to electrically couple to respective terminals of a battery system (e.g., terminals of a busbar, terminals of one or more battery cells, or a chassis ground).

Connectors 230 and 236 may include any suitable type of electric connector such as, for example, a Deutsch DTM connector, a Molex® connector, a spade connector, a connector having pins, a spring terminal connector, a screw terminal connector, a d-sub connector (e.g., DB-9 connector), an RJ45 connector, an RJ11 connector, an Amphenol connector (e.g., a mil-spec twist-lock connector), a BNC connector, a PCB-mount header, any other suitable electrical connector having any combination of interconnect engagements of any suitable gender (e.g., pins, spades, plugs, sockets), or any combination thereof. In some embodiments, a shear wall may include one connector, more than one connector (e.g., as shown illustratively in FIG. 2), or no connectors (e.g., solder pads may be provided to directly affix wires). In some embodiments, respective pins of connectors 230 and 236 may be soldered onto conductive pads of respective conductive traces 270, 272, 274, 276, 278, and 280. In some embodiments, connectors 230 and 236 may include a locking feature, a strain relief feature, any other suitable feature, or any combination thereof.

Extensions 213, 215, 217, 219, and 221 may be configured for arranging respective conductive pads 240, 242, 244, 246, 248, and 250 nearer to measurement locations (e.g., at battery cell terminals, busbars, or other suitable locations). In some embodiments, a shear wall need not include extensions. For example, a shear wall be a rectangle, or nearly a rectangle, and conductive pads may be located along an edge of the sheer wall, or any other suitable location of the shear wall.

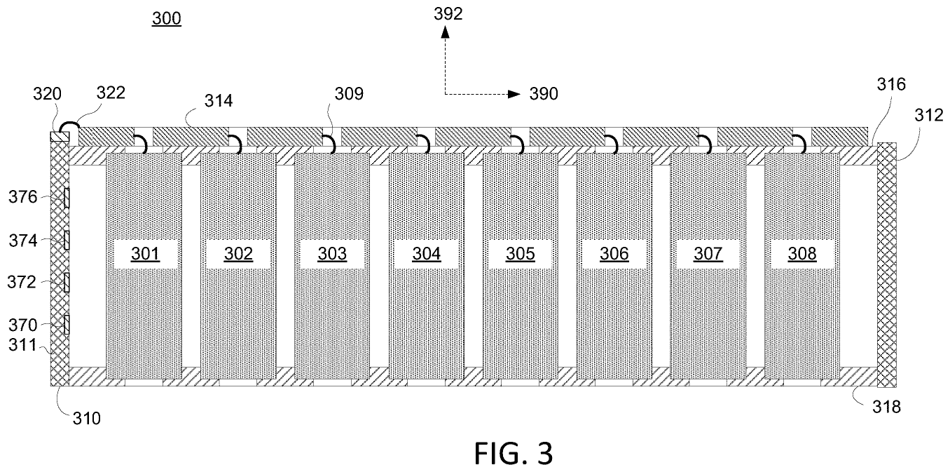

FIG. 3 shows a cross-section view of an illustrative battery system 300, in accordance with some embodiments of the present disclosure. Battery cells 301, 302, 303, 304, 305, 306, 307, and 308 may be arranged and held in place by shrouds 316 and 318. For example, shrouds 316 and 318 may include corresponding reliefs, holes, or both, in an arrangement (e.g., a pattern such as a hexagonal close-packed type pattern), which may maintain spacing and position of battery cells 301-308. Like-polarity terminals of battery cells 301-308 are each connected to busbar 314 via respective jumpers 309 (e.g., in recesses of busbar 314 shown in FIG. 3 as through-holes). For example, each of jumpers 309 (i.e., corresponding to each of battery cells 301-308) may be soldered wires, ultrasonically welded wires, flex tabs which engage with corresponding tabs, springs, or any other suitable electrical jumper from a respective battery cell terminal to busbar 314. The other respective poles (not shown in FIG. 3) of battery cells 301-308 are not connected to busbar 314, and accordingly may be connected to one or more other busbars or other conductive components. For example, as shown in FIG. 3, terminals of battery cells 301-308 are connected in parallel via busbar 314. Further, battery cells 301-308 may be, for example, connected to another busbar (not shown in FIG. 3) via the other polarity terminals of battery cells 301-308 (e.g., the busbars may be connected in series with each other across battery cells 301-308 which accordingly would be connected in parallel).

Shear walls 310 and 312 are connected to shrouds 316 and 318 to provide rigidity to prevent deformation of the arrangement of battery cells 301-308 due to shear forces, or other forces which may cause deformation. For example, shear walls 310 and 312 may help lend rigidity to the arrangement of battery cells 301-308 in directions along axis 390, axis 392, an axis perpendicular to both axis 390 and axis 392 (e.g., directed into the page, or out of the page), or any combination thereof. In a further example, shear walls 310 and 312 may reduce a force on one or more of battery cells 301-308 (e.g., by reducing compressive forces along axis 392 from gravity). In a further example, in the context of an electric car having a battery system, shear walls 310 and 312 may provide rigidity in the event of a vehicle crash (e.g., increased loading from impact and vehicle deformation). In a further example, in the context of an electric car having a battery system, shear walls 310 and 312 may provide spatially controlled rigidity in the event of a vehicle crash (e.g., yield at predetermined locations, and hold rigid in other locations). Shear walls 310 and 312 may be connected to shrouds 316 and 318 by bolted connections, soldered connections, welded connections, brazed connections, crimp connections, tight fitment (e.g., interference press fit, snap features, tongue and groove), any other suitable connection type to form a suitably rigid structure, or any combination thereof.

Shear wall 310 includes support structure 311 and conductive traces 370, 372, 374, and 376, which provide conductive paths partially embedded in support structure 311 (as shown in FIG. 3). Conductive traces may be overlaid on the surface of support structure 311, fully embedded in support structure 311 (e.g., covered by an insulating layer), partially embedded, or any suitable combination thereof. Conductive trace 376, for example, may be coupled to pad 320 (e.g., connected out of the cross-section plane), and may serve as a voltage tap for busbar 314 (e.g., via jumper 322 connecting busbar 314 to conductive pad 320). For example, conductive traces 370, 372, 374, and 376 may be coupled to respective busbars, and also respective terminals of processing equipment (e.g., via a suitable connector and/or cable) configured to measure voltages of the respective busbars over time.

In accordance with the present disclosure, one or more busbars of battery system 300 may be monitored by processing equipment without the need for wire runs near and around the battery cells. In some embodiments, the integration of conductive paths (e.g., conductive traces 370, 372, 374, and 376) into shear wall 310 may provide a convenient path as compared to individual wires. For example, wires may require strain relief, and cable management hardware, and may be susceptible to snagging, shorting, vibrating, or getting in the way during assembly and maintenance. Shear wall 312, as shown in FIG. 3, includes a support structure but no conductive traces. A battery system may include any suitable number of shear walls having any suitable number of conductive traces. For example, a battery system may include two shear walls having conductive traces, on opposite lateral sides of the system. In a further example, a battery system may include four shear walls having conductive traces, on all lateral sides of the system. In a further example, a battery system may include a single shear wall having conductive traces on a lateral side, and shear walls without conductive traces on the remaining lateral sides (e.g., three remaining walls if the battery system is rectangular).

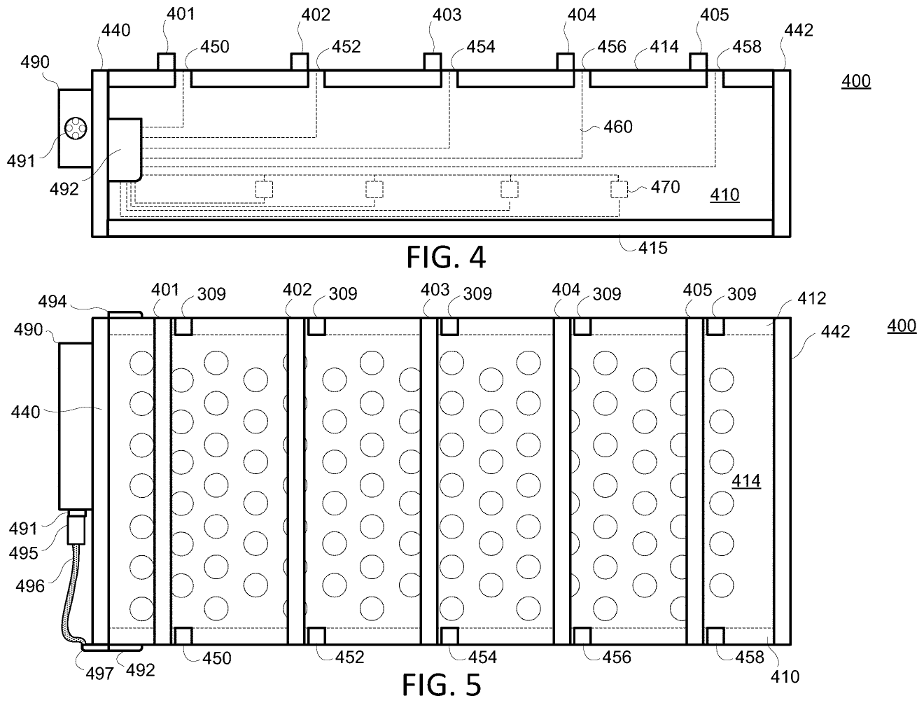

FIG. 4 shows a side view of an illustrative battery system 400, in accordance with some embodiments of the present disclosure. Battery system 400 may include battery cells (not shown), a structure (e.g., shear wall 410 and a shear wall not shown in FIG. 4 on the opposite side of battery system 400, lateral sides 440 and 442, and shrouds 414 and 415), busbars 401-405, and processing equipment 490, along with any other suitable components. Shear wall 410 includes extensions 450, 452, 454, 456, and 458 which protrude through a side of shroud 414, thereby being easily accessible to busbars 401-405. Shear wall 410 includes conductive traces (e.g., conductive trace 460) and sensors (e.g., sensor 470), which are shown as dashed lines in FIG. 4 (e.g., traces are embedded in the support structure of shear wall 410). The conductive traces of shear wall 410 terminate at one end at connector 492. A set of the conductive traces also terminate at extensions 450, 452, 454, 456, and 458, while other conductive traces terminate at sensors.

FIG. 5 shows a top view of illustrative battery system 400 of FIG. 4, in accordance with some embodiments of the present disclosure. Shown additionally in FIG. 5 is cable 496, having connectors 497 and 495, which couple connector 492 of shear wall 410 to connector 491 of processing equipment 490, and shear wall 412, which is across from shear wall 410. In some embodiments, processing equipment may include more than one connector, and be configured to couple to more than one shear wall. In some embodiments, processing equipment may be connected directly to a shear wall, without the need for a cable. For example, in some embodiments, lateral side 440 may include conductive traces which engage with conductive traces of shear wall 410, and the conductive traces of lateral side 440 may also electrically couple to processing equipment 490.

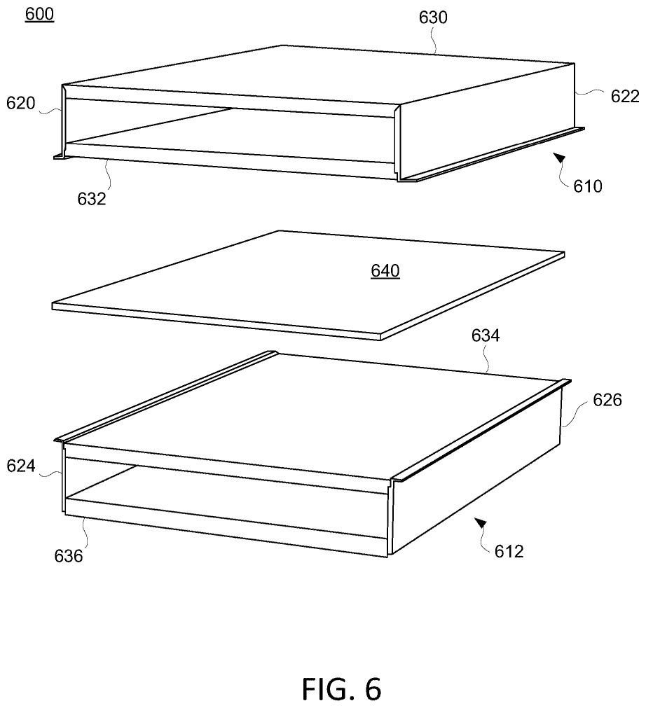

FIG. 6 shows a perspective view of exploded battery system structure 600, including shrouds 630, 632, 634, and 636, and shear walls 620, 622, 624, and 626, in accordance with some embodiments of the present disclosure. Battery system 600 includes two battery modules 610 and 612, connected by mount 640. In some embodiments, mount 640 may include a cooling plate, a structural plate, an isolation barrier, mounting hardware, or any combination thereof. Battery module 610 includes shrouds 630 and 632, which are connected to shear walls 620 and 622. Battery module 612 includes shrouds 630 and 632, which are connected to shear walls 620 and 622.

In some embodiments, battery modules 610 and 612 may each include a plurality of battery cells (not shown in FIG. 6), suitably connected by busbars (not shown in FIG. 6). Each of, or any of, shear walls 620, 622, 624, and 626 may include conductive traces, which may be configured to couple busbars, or terminals of battery cells, to processing equipment. In some embodiments, the processing equipment may couple to conductive traces of one or more of shear walls 620, 622, 624 and 626. A battery system may include any suitable number of battery modules, having any suitable number of shrouds, and any suitable number of shear walls.

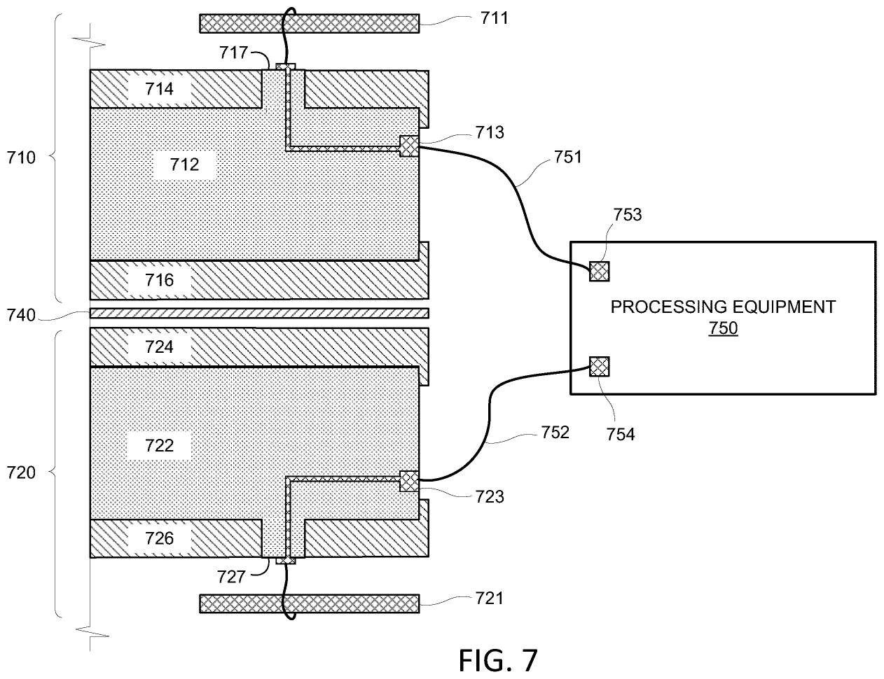

FIG. 7 shows a side view of a cross-section of a portion of illustrative battery system 700, including two battery modules 710 and 712, and processing equipment 750, in accordance with some embodiments of the present disclosure. Battery modules 710 and 720 are coupled by mount 740, which may provide structural support. Battery module 710 includes shear wall 712, shrouds 714 and 716, busbar 711, and conductive trace 713. Battery module 720 includes shear wall 722, shrouds 724 and 726, busbar 721, and conductive trace 723. Conductive trace 713 electrically couples busbar 711 to terminal 753, via cable 751, of processing equipment 750. Conductive trace 723 electrically couples busbar 721 to terminal 754, via cable 752, of processing equipment 750. As shown in FIG. 7, cables 751 and 752 are welded (e.g., ultrasonic welded, or laser welded) to terminals 753 and 754, as well as conductive traces 713 and 723 (e.g., which include electrically conductive pads to allow more conductive material for welding to). In some embodiments, a soldered joint, a screw terminal, a fusible link, any other suitable connection, or any combination thereof, may be used to affix a conductive element to a conductive trace. Processing equipment 750 may determine respective voltages of busbars 711 and 721, and may perform load-balancing, diagnostics, or any other suitable functions, based on the voltages. For example, in some embodiments, every busbar included in one or more battery modules of a battery system may be electrically coupled to processing equipment.

Extensions 717 and 727 are plated with conductive material which are part of respective conductive traces 713 and 723. Although not shown in FIG. 7, shear wall 712 may include one or more extensions along the bottom as well (e.g., protruding through shroud 716). In some arrangements, voltage taps (e.g., terminals of conductive traces) may be accessible from both the top and bottom of a shear wall. For example, a given shear wall design could be used in either battery module 710 or 720.

Shear wall 712 is partially enclosed by shrouds 714 and 716 (e.g., which may be made of plastic) such that there is a substantially continuous length of shroud that is outboard of the shear wall. In some embodiments, shear wall 712 may be joined to each of shrouds 714 and 716 by, for example, adhesive bonding or ultrasonic welding.

A battery system may include any suitable arrangement of shrouds, shear walls, battery cells, busbars, processing equipment, any other suitable hardware, or any suitable combination thereof. For example, while busbars 711 and 721 are spaced away from extensions 717 and 727 in FIG. 7, this is illustrative and busbars 711 and 721 may be positioned directly on extensions 717 and 727, thereby eliminating a separate element to connect busbars 711 and 721 to conductive traces 713 and 723. In a further example with respect to FIG. 4, busbars 401-405 may be positioned directly on top of extensions 450, 452, 454, 456, and 458, thereby eliminating a separate element to connect busbars 401-405 to corresponding conductive traces. In some embodiments, rather than extensions, a shear wall may include recesses that corresponding busbars may rest in. For example, in some such embodiments, the shrouds may be lower and interface with the shear wall via any suitable mechanism. In some embodiments, busbars may be integral to the shroud. For example, busbars may be bolted to, embedded in, or otherwise included as part of, a shroud. In some embodiments, a shear wall need not include extensions or recesses. For example, a shear wall may be rectangular, and may include conductive traces that terminate within the rectangular footprint. In some embodiments, all or part of a shroud may be included as part of a shear wall. In some embodiments, one or more busbars may be integrated as part of a shear wall. In some embodiments, busbars may rest or be affixed to a shear wall, a shroud, or both.

The foregoing is merely illustrative of the principles of this disclosure and various modifications may be made by those skilled in the art without departing from the scope of this disclosure. The above described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations to and modifications thereof, which are within the spirit of the following claims.

What is claimed is:

1. A shear wall configured to provide structural support to a battery system, the shear wall comprising:
a support structure configured to provide rigidity to the battery system along at least one side of the battery system;
a plurality of conductive traces layered onto the support structure, the plurality of conductive paths each comprising:
a respective first terminal configured to be coupled to a busbar of the battery system; and
a respective second terminal configured to be coupled to processing equipment.

2. The shear wall of claim 1, wherein the plurality of conductive paths is a plurality of first conductive paths, the shear wall further comprising:
at least one temperature sensor affixed to the support structure;
at least one second conductive trace layered onto the support structure, comprising:
a first terminal configured to be coupled to the at least one temperature sensor; and
a second terminal configured to be coupled to the processing equipment.

3. The shear wall of claim 2, wherein the at least one temperature sensor comprises a thermistor.

4. The shear wall of claim 1, further comprising a first electrical connector comprising respective pins coupled to each of the respective second terminals.

5. The shear wall of claim 4, wherein:
the processing equipment is coupled to a second electrical connector; and
each of the second terminals is configured to be coupled to the processing equipment by connecting the first electrical connector and the second electrical connector.

6. The shear wall of claim 1, wherein the support structure comprises a flame-resistant glass-epoxy laminate.

7. The shear wall of claim 1, wherein the plurality of conductive traces comprise copper tracks bonded to the support structure.

8. The shear wall of claim 1, wherein the support structure comprises at least one extension comprising a conductive pad coupled to a respective first terminal, and wherein the conductive pad is configured to be coupled to the busbar.

9. The shear wall of claim 1, wherein the busbar is coupled to a plurality of like-polarity terminals of a respective plurality of battery cells.

10. The shear wall of claim 1, wherein each of the respective first terminals is configured to be coupled to the busbar by a welded connection.

11. A battery system comprising:
processing equipment;
a plurality of battery cells;
a plurality of busbars connecting the plurality of battery cells;
at least one shroud configured to maintain an arrangement of the plurality of battery cells;
a shear wall configured to provide structural support to the at least one shroud and the arrangement of the plurality of battery cells, the shear wall comprising:
a support structure coupled to the at least one shroud along at least one side of the at least one shroud;
a plurality of conductive traces affixed to the support structure, the plurality of conductive traces each comprising:
a respective first terminal configured to be coupled to a respective busbar; and
a respective second terminal configured to be coupled to the processing equipment.

12. The battery system of claim 11, wherein the plurality of conductive traces is a plurality of first conductive traces, the battery system further comprising:
at least one temperature sensor embedded in the support structure;
at least one second conductive trace embedded in the support structure, comprising:
a first terminal configured to be coupled to the at least one temperature sensor; and
a second terminal configured to be coupled to the processing equipment.

13. The battery system of claim 12, wherein the at least one temperature sensor comprises a thermistor.

14. The battery system of claim 11, wherein the shear wall comprises an electrical connector comprising respective pins coupled to each of the respective second terminals.

15. The battery system of claim 14, wherein:
the processing equipment is coupled to a second electrical connector; and
each of the second terminals is configured to be coupled to the processing equipment by connecting the first electrical connector and the second electrical connector.

16. The battery system of claim 11, wherein the support structure comprises a flame-resistant glass-epoxy laminate.

17. The battery system of claim 11, wherein the plurality of conductive traces comprise copper tracks bonded to the support structure.

18. The battery system of claim 11, wherein the support structure comprises at least one extension comprising a conductive pad coupled to a respective first terminal, and wherein the conductive pad is configured to be coupled to the busbar.

19. The battery system of claim 11, wherein each of the plurality busbars is connected to respective like-polarity terminals of a group of battery cells of the plurality of battery cells.

20. The battery system of claim 11, wherein each of the respective first terminals is configured to be coupled to a respective busbar of the busbars by a welded connection.

21. The battery system of claim 11, wherein the processing equipment is configured to measure a voltage of at least one of the second terminals.
